(19) United States
(12) Patent Application Publication
(10) Pub. No.: US 2024/0113002 A1
(43) Pub. Date: Apr. 4, 2024

(54) EDGE-PROTECTED SEMICONDUCTOR DEVICE ASSEMBLIES AND ASSOCIATED METHODS

(71) Applicant: Micron Technology, Inc., Boise, ID (US)

(72) Inventors: Ya Ling Huang, Taichung (TW); Jong Sik Paek, Taichung (TW); Lihao Lyu, Hsinchu City (TW); Syuan-Ye Chen, Taichung (TW)

(21) Appl. No.: 18/374,996

(22) Filed: Sep. 29, 2023

Related U.S. Application Data
(60) Provisional application No. 63/412,250, filed on Sep. 30, 2022.

(51) Int. Cl. H01L 23/498; H01L 21/48; H01L 21/56; H01L 23/31; H01L 25/065

(52) U.S. Cl. CPC H01L 23/49822; H01L 21/4857; H01L 21/565; H01L 23/3114; H01L 23/49816; H01L 25/0657; H01L 2225/0651

(57) ABSTRACT

The present technology can include a semiconductor device assembly comprising an RDL with a top surface and a side surface intersecting the top surface. The assembly can further comprise a semiconductor device coupled to the top surfaces, and a mold material encasing the semiconductor device (when included) and directly coupled to at least a portion of the top surface and the side surface of the RDL. In other embodiments, the assembly can comprise an RDL with a top surface, a bottom surface opposite thereto, and a sloped side surface extending between the top surface and the bottom surface. The assembly similarly can further comprise a semiconductor device coupled to the top surface, and a mold material encasing the semiconductor device and directly coupled to at least a portion of the top surface and the side surface of the RDL.

### CROSS-REFERENCE TO RELATED APPLICATION(S)

The present application claims priority to U.S. Provisional Patent Application No. 63/412,250, filed Sep. 30, 2022, the disclosure of which is incorporated herein by reference in its entirety.

### TECHNICAL FIELD

The present technology is generally related to semiconductor device assemblies, and, more specifically, to edge-protected redistribution layer interposers within semiconductor device assemblies.

### BACKGROUND

Microelectronic devices, such as memory devices and microprocessors, and other electronics typically include one or more semiconductor devices and/or components attached to a substrate and encased in a protective covering. The devices and/or components include at least one functional feature, such as memory cells, processor circuits, or interconnecting circuitry, etc. Each device and/or component commonly includes an array of small bond pads electrically coupled to the functional features therein for interconnection with other devices and/or components.

Manufacturers are under increasing pressure to reduce the space occupied by these devices and components, while simultaneously increasing the capacity and/or speed of operation for the resulting semiconductor device assemblies. One approach taken to reduce space is implementing a redistribution layer (RDL) as an interposer or a base assembly semiconductor device. This generally includes forming an RDL and coupling semiconductor devices thereon, then encasing the assembly in a mold material before singulating individual semiconductor assemblies. While these implemented RDLs can reduce a height of the resulting assemblies, their susceptibility to bending and/or damage from impurities, as well as their limited operating capacity presents manufacturing and operational challenges.

### BRIEF DESCRIPTION OF THE DRAWINGS

FIG. 1 is a cross-sectional side view of a semiconductor device assembly including an edge-protected RDL interposer, configured in accordance with some embodiments of the present technology.

FIG. 2 is a cross-sectional side view of a semiconductor device assembly including an edge-protected RDL interposer, configured in accordance with some embodiments of the present technology.

FIG. 3 is a cross-sectional side view of a semiconductor device assembly including an edge-protected RDL interposer, configured in accordance with some embodiments of the present technology.

FIGS. 4-11 illustrate a process for manufacturing a semiconductor device assembly including an edge-protected RDL interposer in accordance with some embodiments of the present technology.

FIG. 12 is a flow diagram illustrating a process for producing semiconductor devices in accordance with some embodiments of the present technology.

FIG. 13 is a schematic diagram illustrating a semiconductor device assembly incorporating the present technology, configured in accordance with some embodiments of the present technology.

The drawings have not necessarily been drawn to scale. Similarly, some components or operations can be separated into different components or combined into a single assembly in some implementations of the present technology. While the technology is amenable to various modifications and alternative forms, specific implementations have been shown by way of example in the drawings and are described in detail below.

### DETAILED DESCRIPTION

Traditionally, semiconductor device assemblies or packages including a device stack have an assembly semiconductor device with the device stack coupled to a top surface thereof. Further, some semiconductor device assemblies can include the assembly semiconductor device alone. To reduce the height of these assemblies, the assembly devices can be implemented as redistribution layer interposers (e.g., RDL interposers). These RDL interposers can be an alternative to taller assembly devices, such as printed circuit boards, thereby shorting the overall height of the assembly. RDL interposers and their resultant assemblies, however, present unique manufacturing and operational challenges.

To prepare an RDL interposer, multiple layers of dielectric and conductive material are formed on a carrier, with an area of the multiple layers corresponding with to-be-formed semiconductor device assemblies (e.g., assembly sections). In the areas between these assembly sections (e.g., separation sections), only dielectric material is present in each layer of the RDL interposer. That is, conductive material within the multiple layers forming functional features of the to-be-formed semiconductor device assemblies is exclusively within the assembly sections of the RDL interposer. Once the multiple layers are complete, within each of the assembly sections, and when included, one or more semiconductor devices are coupled to a top surface of the RDL interposer. A mold material is provided over the RDL interposer and the semiconductor devices, creating an intermediary assembly that is separated from the carrier. The separated intermediary assembly is then cut along the separation sections to isolate the assembly sections, thereby forming the individual semiconductor device assemblies. However, in cutting the intermediary assembly, portions of the RDL interposer are exposed at each side of the formed individual assemblies.

Manufacturing challenges presented by assemblies with RDL interposers are at least associated with the layers of the RDL interposer within the separation sections excluding conductive materials. By excluding conductive material—and the structural support provided thereby—and only having dielectric material, RDL interposers are susceptible to warpage and/or delamination at the separation sections during assembly processing. This can be caused by inconsistent expansion and contraction of the dielectric material in the separation sections relative to the expansion and contraction of the conductive and dielectric materials in the assembly sections. Further, this inconsistent expansion and contraction is multiplied by each the number of layers within the RDL interposer. Therefore, RDL interposers are limited in the number of layers that can be included in the RDL interposer, thereby limiting the operational capacity of the resulting assembly.

Operational challenges presented by assemblies with RDL interposers are at least associated with a portion of the RDL interposer being exposed at a side surface of the resulting assemblies, as well as RDL interposers' general susceptibility to bending. For example, when the semiconductor devices are formed by cutting the intermediary assembly along the separation sections, a cross-section of each of the RDL interposers is exposed on at least one side of each semiconductor device assembly. This exposed portion of the RDL interposer can be contaminated by impurities from the surrounding environment, leading at least to layer delamination and/or assembly failure. Further, given their thin profile, RDL interposers bendability can lead to delamination at the exposed portions thereof with lower layers pulling away from the assembly.

The present technology relates to semiconductor device assemblies with assembly substrate devices implemented as RDL interposers with protected edges, and associated methods of manufacture. For example, these assemblies can include an RDL interposer encased in a mold material, and with or without multiple stack devices carried by an RDL interposer. The mold material can fully encase the exposed surfaces of the stack devices, and/or can further cover a top surface and one or more side surfaces of the RDL interposer. Sides of the RDL interposer can be covered by the mold material by selectively applying and etching dielectric material when forming layers of the RDL interposer to maintain a gap between assembly sections. Then, when the mold material is provided, mold material can fill the exposed gap and bond with, and cover, the sides of the RDL interposer. Then, when the intermediary assembly is removed from the carrier and cut along the separation sections—along the gaps filled with mold material—the sides of the RDL interposer are supported and protected by the mold material in the final assembly.

By providing semiconductor device assemblies with edge-protected RDL interposers, these assemblies can have a minimal height while overcoming at least the above noted challenges of RDL interposers, in addition to providing other benefits. For example, assemblies corresponding with the present technology can exclude dielectric material in the separation sections during RDL interposer formation. Instead, on the carrier, separation sections can include a gap between assembly sections, thereby removing RDL interposer portions solely including dielectric material (e.g., exclusive of conductive material). By removing portions of the RDL interposer primarily or entirely comprising dielectric material, the RDL interposer is less susceptible to warpage and/or delamination between assembly sections. Therefore, assemblies with edge-protected RDL interposers can include additional RDL interposer layers, thereby increasing the overall operating capacity of their resulting assemblies; and can decrease the number of inoperable or prematurely failing assemblies. Further, by including mold material on side surfaces of the RDL interposer (e.g., by edge-protecting the RDL interposers), the RDL interposer can be protected from environmental impurities and instances of delamination can be reduced, thereby increasing device longevity.

In some embodiments, the present technology can include a semiconductor device assembly comprising an RDL with a top surface and a side surface intersecting the top surface. The assembly can further comprise a mold material encasing and directly coupled to at least a portion of the top surface and the side surface of the RDL. In some embodiments, the present technology can further include a semiconductor device coupled to the top surface, and the mold material can further encase the semiconductor device. In other embodiments, the assembly can comprise an RDL with a top surface, a bottom surface opposite thereto, and a sloped side surface extending between the top surface and the bottom surface. The assembly similarly can further comprise a semiconductor device coupled to the top surface, and a mold material encasing the semiconductor device and directly coupled to at least a portion of the top surface and the side surface of the RDL.

These assemblies can be manufactured by providing a carrier for forming the assemblies thereon. The surface of the carrier can include sections corresponding to a first semiconductor device and to a second semiconductor device, and the first semiconductor device section can be separated from the second semiconductor device section by a separation gap. A first RDL layer can be formed on the carrier over (e.g., within) the first and second semiconductor device sections, and over the separation gap. Then, dielectric material from the first RDL layer over the separation gap can be removed. A second RDL layer can be formed on the first RDL and the carrier over the first and second semiconductor device sections, and over the separation gap. Then, dielectric material from the second RDL layer over the separation gap can be removed.

A mold material can be provided over the carrier, the first RDL, and the second RDL, and over and within the separation gap. The carrier can be removed once the mold material is cured. A first semiconductor device assembly and a second semiconductor device assembly can be separated from one another by cutting along the separation gap. After separation, a portion of the mold material from within the separation gap remains covering a side surface of the first and the second RDL layers of the first semiconductor device assembly, and covering a side surface of the first and the second RDL layers of the second semiconductor device assembly.

For ease of reference, the semiconductor device and other components are sometimes described herein with reference to top, bottom, left, right, lateral, vertical, uppermost, lowermost, or other similar directional terms relative to the spatial orientation of the embodiments described and/or shown in the figures. The semiconductor devices described herein and modifications thereof can be moved to and/or used in different spatial orientations without changing the structure and/or function of the disclosed embodiments of the present technology.

In the Figures, identical or similar reference numbers (e.g., 100 as to 200, 110 as to 210, etc.) identify generally similar and/or identical elements. Many of the details, dimensions, and other features shown in the Figures are merely illustrative of particular embodiments of the disclosed technology. Accordingly, other embodiments can have other details, dimensions, and/or features without departing from the spirit or scope of the disclosure. In addition, those of ordinary skill in the art will appreciate that further embodiments of the various disclosed technologies can be practiced without several of the details described below.

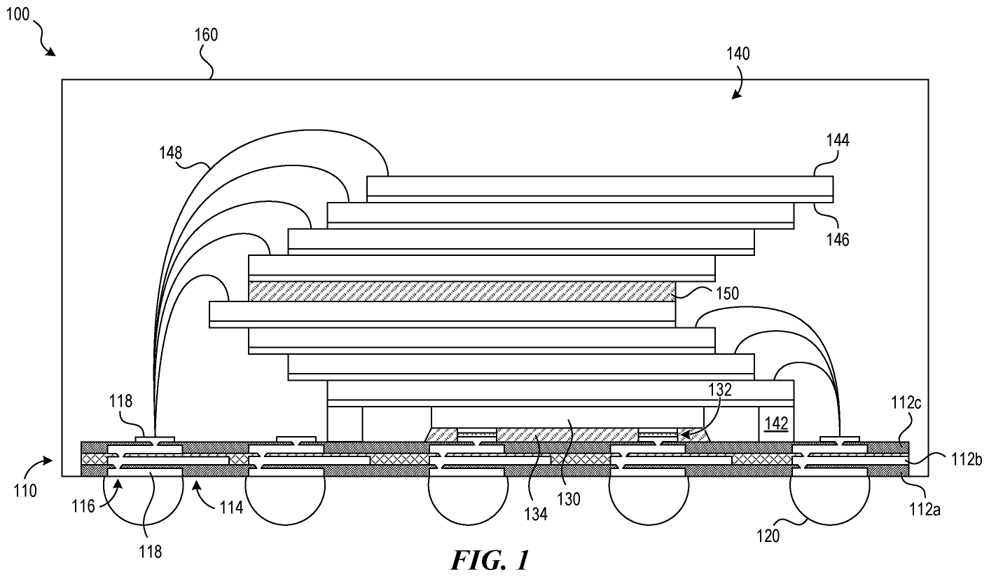

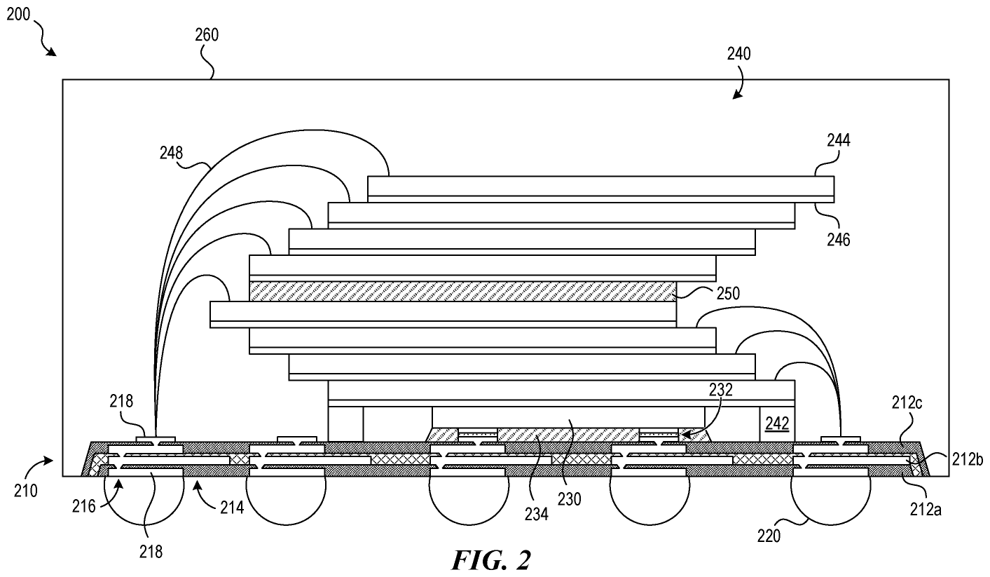

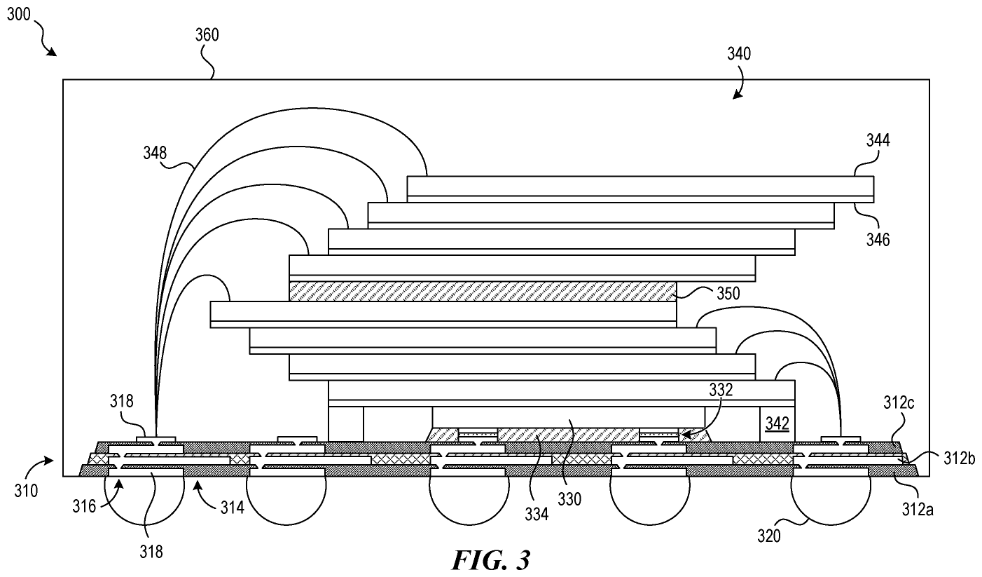

FIG. 1 is a cross-sectional side view of a semiconductor device assembly 100 including an edge-protected RDL interposer 110 with flat side surfaces, configured in accordance with some embodiments of the present technology. The assembly 100 can be a first example of an edge-protected RDL interposer implemented in a semiconductor device assembly. However, some or all aspects of the assembly 100, and the elements and/or benefits thereof, can correspond with other examples of edge-protected RDL interposers implemented in semiconductor device assemblies, such as the edge-protected RDL interposer 210 of FIG. 2, infra, and/or the edge-protected RDL interposer 310 of FIG. 3, infra.

Referencing FIG. 1, the assembly 100 can include the RDL interposer 110 with a top surface thereof carrying a semiconductor controller 130 and a semiconductor device stack 140. The device stack 140 can be supported by one or more spacers 142, and can include a plurality of stacked semiconductor devices 144 coupled together by adhesive layers 146. An upper portion of the device stack 140 can be coupled to and separated from a lower portion of device stack 140 by a mating compound 150 (e.g., die attach film, film over wire, etc.). The stack devices 144 can be in electric communication with the RDL interposer 110 via wire traces 148, and in electric communication with one another via vertical interconnections therebetween (not illustrated). A mold material 160 can bond to and/or encase the controller 130, the device stack 140, and the top and side surfaces of the RDL interposer 110. The RDL interposer 110 can include multiple RDL interposer layers 112 having dielectric material 114 and conductive material 116 therein. Further, each of the layers 112 can have a substantially flat and/or sloped side surface, coplanar with the side surfaces of the layers there above and below. In some embodiments, the assembly 100 can exclude the controller and/or the device stack 140. Further, in some embodiments, the assembly 100 can exclusively include the RDL interposer 110, the elements thereof, and the mold material 160.

For example, as shown, the RDL interposer 110 includes a first layer 112a, a second layer 112b, and a third layer 112c, each with flat side surfaces substantially coplanar with corresponding side surfaces of the layer(s) 112 there above and below. The first layer 112a is a bottom or lowermost layer forming the bottom surface of the RLD interposer 210 and the assembly 200, and can include substantially flat, vertical sides. The second layer 112b is a middle or intermediary layer above the first layer 112a, and can include substantially flat sides coplanar with the sides of the first layer 112a. The third layer 112c is a top or uppermost layer forming the top surface of the RDL interposer 210, and can include substantially flat sides coplanar with the sides of the first layer 112a and/or the second layer 112b. Collectively, the side surfaces of the first layer 112a, the second layer 112b, and the third layer 112c can define the side surface of the RDL interposer 110.

Each of the layers 112 can include the conductive material 116 forming functional features within the RDL interposer 110, such as traces, interconnects, circuitry, bond pads 118, and/or any other conductive elements supporting operation of the RDL interposer 110 and/or devices interconnected therewith. The conductive material 116 can be insulated and/or separated by the dielectric material 114 therebetween. Although as illustrated, the assembly 100 includes three layers 112, in some embodiments, the assembly 100 can include as few as one layer 112, or more than three layers 112 (e.g., 4, 5, 6, etc., in total). Each of the additional layers 112 can similarly have flat sides substantially coplanar with the sides of the layer(s) 112 there above and below. Additionally, the mold material 160 can bond to and/or encase the sides of the additional layer(s). The bond pads 118 can be at the top and/or bottom surface of the RDL interposer 110, and solder balls 120 can be coupled to one or more thereof.

By protecting the sides surfaces of the layers 112 of the RDL interposer 110 with the mold material 160 (e.g., by including an edge-protected RDL interposer 110), the assembly 100 can provide at least the benefits identified above of the disclosed technology, and regarding the assembly 200 of FIG. 2, infra, and the assembly 300 of FIG. 3, infra. For example, the assembly 100 can have a minimal height, while allowing for additional layers within the RDL interposer 110. Further, the assembly 100 can be less likely to experience warpage, delamination, impurity contamination, and/or other similar defects, potentially leading to reduced operation and/or failure of the assembly 100. Additionally, the structural integrity of the assembly 100 can be increased by including the mold material 160 as coupled to both the top surface and the side surfaces of the RDL interposer 110. The assembly 100 can therefore provide superior operating capacity in a smaller assembly package than traditional assemblies, in addition to providing RDL-interposer-based semiconductor assemblies, specifically, with greater longevity.

The controller 130 and/or each of the devices 144 can be a memory and/or processing device, such as a memory die (e.g., a NAND die, a DRAM die, a NOR die, a PCM die, a FeRAM die, etc.), a graphics processing unit, a logic device, an interposer, a PCB, or any similar semiconductor device with functional features configured to facilitate operation of the assembly 100. The controller 130 and/or each of the devices 144 can include an upper surface and a lower surface opposite the upper surface. The controller 130 can be physically and electrically coupled to the RDL interposer 110 at the lower surface thereof by interconnection structures 132 via one or more corresponding bond pads 118 of the RDL interposer 110. A gap between the controller 130 and the RDL interposer 110 can be filled with an underfill material 134 to prevent impurities therein.

As shown, the device stack 140 can be supported by the spacers 142 and the controller 130. The device stack 140 can include eight stack devices 144. Four of the devices 144 can be shingled in a first direction, exposing bond pads on the top surfaces thereof. Four of the devices 144 can be shingled in a second direction (e.g., reverse shingled) and similarly exposing bond pads on the top surfaces thereof. In some embodiments, the assembly 100 can include fewer (e.g., 1, 2, 3, 4, 5, 6, 7) or additional (e.g., 16, 25 in total, etc.) stack devices 144, and/or the assembly 100 can include additional (e.g., 2, 4 in total, etc.) device stacks 140. Further, the assembly can include the stack devices 144 of one or more of the device stacks 140 in a single, shingled portion; or one or more of the device stacks 140 can include additional (e.g., 3, 4 in total, etc.) singled and/or reverse-shingled portions. One or more of the stack devices 144 can be coupled to the preceding stack device 144 by an adhesive, such as die adhesive film (DAF), and/or the stack devices 144 can be interconnected with solder and/or surface bonding.

The traces within the RDL interposer 110 can extend between two or more of the bond pads 118. The controller 130 and one or more of the devices 144 can be in communication (e.g., electric communication, interconnection) with one or more functional features within the RDL interposer 110, the controller 130, and/or the stack devices 144, respectively, via the traces. Further, by these interconnections and the solder balls 120, the interposer 110, the controller 130, and/or the stack devices 144 can be in communication with elements external to the assembly 100. In some embodiments, the assembly 100 can exclude the controller 130. Although as illustrated, the bond pads 118 at the top surface of the RDL interposer 110 are shown as a single bond pad 118, the assembly 100 can include multiple of the bond pads 118 corresponding with each stack device 144 at the top surface along a depth of the assembly 100 (e.g., into the drawing). Similarly, the assembly 100 can include multiple of the wire traces 148 extending between each stack device 144 and a corresponding one of the multiple bond pads 118.

The dielectric material 114 can be any suitable dielectric material insulating portions of the conductive material 116 and partially forming the layers 112 of the RDL interposer 110. For example, the dielectric material can include TEOS, SiN, SiO, SiCN, or any similar, suitable dielectric material, or a combination thereof. The conductive material 116, the bond pads 118, and the interconnection structures 132 of the assembly 100 can each include any suitable conductive material such as, for example, copper, gold, silver, aluminum, tungsten, cobalt, nickel, or any similar, suitable conductive material, or combination thereof, forming functional features within the layers of the RDL interposer 110.

FIG. 2 is a cross-sectional side view of a semiconductor device assembly 200 including an edge-protected RDL interposer 210 with sloped, layered side surface, configured in accordance with some embodiments of the present technology. The assembly 200 can be a second example of an edge-protected RDL interposer implemented in a semiconductor device assembly. However, some or all aspects of the assembly 200, and the elements and/or benefits thereof, can correspond with other examples of edge-protected RDL interposers implemented in semiconductor device assemblies, such as the edge-protected RDL interposer 110 of FIG. 1, and/or the edge-protected RDL interposer 310 of FIG. 3, infra.

Referencing FIG. 2, the assembly 200 can include the RDL interposer 210 with a top surface thereof carrying a semiconductor controller 230 and a semiconductor device stack 240. The device stack 240 can be supported by one or more spacers 242, and can include a plurality of stacked semiconductor devices 244 coupled together by adhesive layers 246. An upper portion of the device stack 240 can be coupled to and separated from a lower portion of device stack 240 by a mating compound 250 (e.g., die attach film, film over wire, etc.). The stack devices 244 can be in electric communication with the RDL interposer 210 via wire traces 248, and in electric communication with one another via vertical interconnections therebetween (not illustrated). A mold material 260 can bond to and/or encase the controller 230, the device stack 240, and the top and sloped, layered side surfaces of the RDL interposer 210. The RDL interposer 210 can include multiple RDL interposer layers 212 having dielectric material 214 and conductive material 216 therein. Further, each of the layers 212 above one or more preceding layers 212 can include sloped side legs extending over the preceding layers 212 and aligned with a bottom surface of the RDL interposer 210 and the assembly 200. In one embodiment, the slope of the side legs extending over the preceding layers 212 is result of a process of forming RDL interposer layers 212 using selectively curing using photomasking and removal of uncured portion. In some embodiments, the assembly 200 can exclude the controller and/or the device stack 240. Further, in some embodiments, the assembly 200 can exclusively include the RDL interposer 210, the elements thereof, and the mold material 260.

For example, as shown, the RDL interposer 210 includes a first layer 212a, a second layer 212b, and a third layer 212c. The first layer 212a is a bottom or lowermost layer forming the bottom surface of the RLD interposer 210 and the assembly 200, and can include substantially flat, vertical and/or sloped sides. The second layer 212b is a middle or intermediary layer above the first layer 212a, and can include side legs extending laterally past the sides of the first layer 212a and down to align with the bottom surface of the RLD interposer 210 and the assembly 200. The third layer 212c is a top or uppermost layer forming the top surface of the RDL interposer 210, and can include side legs extending laterally past the sides of the first layer 212a and the side legs of the second layer 212b, and extending down to align with the bottom surface of the RLD interposer 210 and the assembly 200. The exterior of the side legs of the third layer 212c can define the side surfaces of the RDL interposer 210.

Each of the layers 212 can include the conductive material 216 forming functional features within the RDL interposer 210, such as traces, interconnects, circuitry, bond pads 218, and/or any other conductive elements supporting operation of the RDL interposer 210 and/or devices interconnected therewith. The conductive material 216 can be insulated and/or separated by the dielectric material 214 therebetween. Although as illustrated, the assembly 200 includes three layers 212, in some embodiments, the assembly 200 can include as few as two layers 212, or more than three layers 212 (e.g., 4, 5, 6, etc., in total). Each of the additional layers 212 can similarly have side legs extending laterally past the sides and/or side legs of the preceding layers 212, and down to align with the bottom surface of the RDL interposer 210 and the assembly 200. Additionally, the mold material 260 can bond to and/or encase the sloped, layered side surface of the RDL interposer 210, as formed by the side legs of the uppermost additional layer 212. The bond pads 218 can be at the top and/or bottom surface of the RDL interposer 210, and solder balls 220 can be coupled to one or more thereof.

By protecting the sides surfaces of the layers 212 of the RDL interposer 210 with the mold material 260 (e.g., by including an edge-protected RDL interposer 210), the assembly 200 can provide at least the benefits identified above of the disclosed technology, and regarding the assembly 100 of FIG. 1 and the assembly 300 of FIG. 3, infra. Further, by including the RDL interposer 210 with sloped, layered sides, the assembly 200 can at least further decrease the likelihood for delamination of the layers 212. Delamination of the layers 212 can decrease at least because portions of the intermediary and the uppermost layers 212b, 212c encase the sides of the layer(s) 212 thereunder, and therefore the layers 212 bond together at contacting top and bottom surfaces (e.g., along the middle of the layers 212), in addition to contacting side surfaces.

FIG. 3 is a cross-sectional side view of a semiconductor device assembly 300 including an edge-protected RDL interposer 310 with a sloped, stepped side surface, configured in accordance with some embodiments of the present technology. The assembly 300 can be a third example of an edge-protected RDL interposer implemented in a semiconductor device assembly. However, some or all aspects of the assembly 300, and the elements and/or benefits thereof, can correspond with other examples of edge-protected RDL interposers implemented in semiconductor device assemblies, such as the edge-protected RDL interposer 110 of FIG. 1, and/or the edge-protected RDL interposer 210 of FIG. 2.

Referencing FIG. 3, the assembly 300 can include the RDL interposer 310 with a top surface thereof carrying a semiconductor controller 330 and a semiconductor device stack 340. The device stack 340 can be supported by one or more spacers 342, and can include a plurality of stacked semiconductor devices 344 coupled together by adhesive layers 346. An upper portion of the device stack 340 can be coupled to and separated from a lower portion of device stack 340 by a mating compound 350 (e.g., die attach film, film over wire, etc.). The stack devices 344 can be in electric communication with the RDL interposer 310 via wire traces 348, and in electric communication with one another via vertical interconnections therebetween (not illustrated). A mold material 360 can bond to and/or encase the controller 330, the device stack 340, and the top and sloped, layered side surfaces of the RDL interposer 310. The RDL interposer 310 can include multiple RDL interposer layers 312 having the dielectric material 314 and conductive material 316 therein. Further, the layers 312 can have progressively narrower widths and/or depths (e.g., into the page of FIG. 3) from the bottom of the assembly 300 up. That is, the layers 312 can be tiered such that the RDL interposer 310 has sloped, stepped sides. In one embodiment, the layers 312 are using a process of forming RDL interposer layers 312 using selectively curing using photomasking and removal of uncured portion. In some embodiments, the assembly 300 can exclude the controller and/or the device stack 340. Further, in some embodiments, the assembly 300 can exclusively include the RDL interposer 310, the elements thereof, and the mold material 360.

For example, as shown, the RDL interposer 310 includes a first layer 312a, a second layer 312b, and a third layer 312c. The first layer 312a is a bottom or lowermost layer forming the bottom surface of the RLD interposer 310 and the assembly 300, and can include substantially flat, vertical and/or sloped sides separated by a first width. The second layer 312b is a middle or intermediary layer above the first layer 312a, and include substantially flat, vertical and/or sloped sides separated by a second width, less than the first width. The third layer 312c is a top or uppermost layer forming the top surface of the RDL interposer 310, and can include substantially flat, vertical and/or sloped sides separated by a third width, less than the second width. Collectively, the side surfaces and the exposed portions of the top surfaces of the first layer 312a, the second layer 312b, and the third layer 312c define the side surface of the RDL interposer 310.

Each of the layers 312 can include the conductive material 316 forming functional features within the RDL interposer 310, such as traces, interconnects, circuitry, bond pads 318, and/or any other conductive elements supporting operation of the RDL interposer 310 and/or devices interconnected therewith. The conductive material 316 can be insulated and/or separated by the dielectric material 314 therebetween. Although as illustrated, the assembly 300 includes three layers 312, in some embodiments, the assembly 300 can include as few as two layers 312, or more than three layers 312 (e.g., 4, 5, 6, etc., in total). Each of the additional layers 312 can similarly have a width less than the width of the preceding layer. Additionally, the mold material 360 can bond to and/or encase the sloped, stepped surfaces of the RDL interposer 310, thereby bonding and/or encasing the exposed portions of the top and the side surface of the layers 312. The bond pads 318 can be at the top and/or bottom surface of the RDL interposer 310, and solder balls 320 can be coupled to one or more thereof.

By protecting the sides surfaces of the layers 312 of the RDL interposer 310 with the mold material 360 (e.g., by including an edge-protected RDL interposer 310), the assembly 300 can provide at least the benefits identified above of the disclosed technology, and regarding the assembly 100 of FIG. 1 and the assembly 200 of FIG. 2. Further, by including the RDL interposer 310 with sloped, stepped sides, the assembly 300 can at least further decrease the likelihood for delamination of the layers 312. Delamination of the layers 312 can decrease at least because the mold material 360 can bond directly with the exposed portions of the top side surfaces of the layers 312, in addition to the side surfaces of the layers 312, thereby decreasing the likelihood layers 312 will pull apart from the bottom of the assembly 300.

In some embodiments, a semiconductor device assembly including an edge-protected RDL interposer can have an RDL interposer with layers therein corresponding with one or more of the layers from the interposer 110 of FIG. 1, the interposer 210 of FIG. 2, and the interposer 310 of FIG. 3. That is, the semiconductor device assembly can include a hybrid RDL interposer including flat side surfaces; sloped, layered side surfaces; and/or sloped, stepped side surfaces. For example, the semiconductor device assembly can include a first layer with flat and/or sloped sides surface separated by a first width; a second layer with side legs extending past the side surfaces of the first layer, and to the bottom surface of the first layer; and a third layer with flat and/or sloped side surfaces separated by a third width, less than the first width.

As a further example, the semiconductor device assembly can include a first layer with flat and/or sloped sides separated by a first width; a second layer with flat and/or sloped sides separated by a second width the same as or less than the first width; and a third layer with side legs extending past the side surfaces of the second layer, or past the side surfaces of the first layer and the second layer, and to the bottom surface of the second layer or the first layer, respectively. Additionally, the semiconductor device assembly can include an RDL interposer with two or more layers with side surfaces of each layer corresponding with any one of the flat side surfaces; sloped, layered side surfaces; and/or sloped, stepped side surfaces.

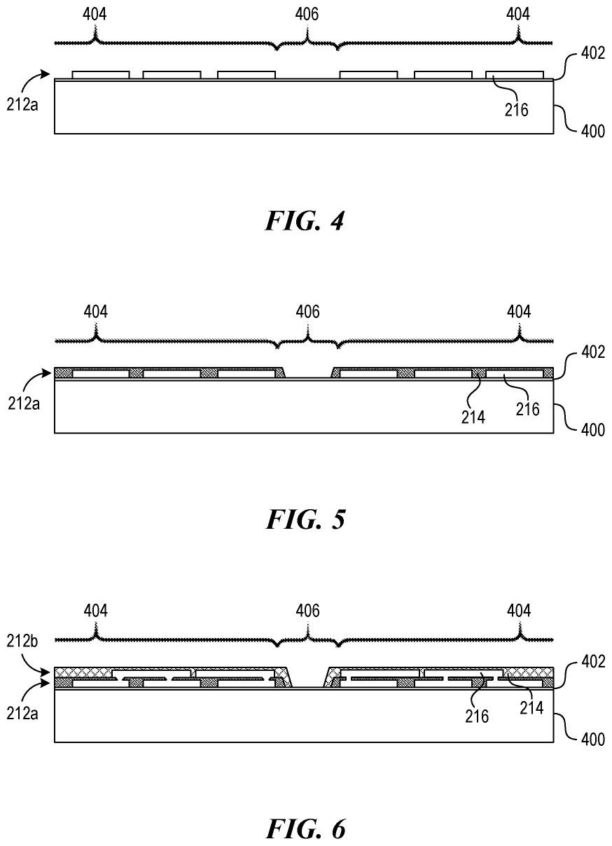

FIGS. 4-11 illustrate a process for manufacturing a semiconductor device assembly including an edge-protected RDL interposer, such as the assembly 100 of FIG. 1, the assembly 200 of FIG. 2, or the assembly 300 of FIG. 3, in accordance with some embodiments of the present technology. Specifically, FIGS. 4-11 illustrate the manufacturing process of a right portion of a first assembly and a left portion of a second assembly, each including an edge-protected RDL interposer and corresponding with the assembly 200 of FIG. 2.

Referencing FIGS. 4-11, the process may generally include sequentially forming layers of an RDL interposer on a carrier, such as a glass carrier, with sections of the RDL interposer corresponding with the location of a to-be-formed semiconductor device assembly (e.g., assembly sections), and sections of the RDL interposer separating the assembly sections (e.g., separation sections). When forming each layer, a gap can be provided between the assembly sections in the separation sections, exposing a portion of the carrier (e.g., an exposed portion). One or more controllers and/or semiconductor devices can be coupled to the top of the RDL interposer, and a mold material can cover and encase the controllers, the devices, and/or the RDL interposer (e.g., forming an intermediary assembly). Further, the mold material can fill the exposed gap, touching the carrier, and covering (e.g., protecting) the edges of the RDL interposer. The intermediary assembly can be separated from the carrier and cut along the separation sections of the RDL interposer, forming the complete assemblies with edge-proposed RDL interposers. Although as illustrated two semiconductor device assemblies are formed, the process can be used to form additional (e.g., 4, 16, 100, 1000, etc.) semiconductor device assemblies including edge-protected RDL interposers, or a position thereof, on a single carrier.

FIG. 4 illustrates conductive material 216 of first RDL interposer layers 212a formed on a release layer 402 of a carrier 400. As shown, the conductive material 216 is formed within, and corresponding to, assembly sections 404 of two to-be-formed RDL interposers, and an exposed gap is maintained therebetween in a separation section 406. The conductive material 216 can be formed using any suitable additive manufacturing process such as, for example, sputtering, physical vapor deposition (PVD), electroplating, lithography, or any other similar process(es), or combination thereof. Further, forming the conductive material 216 can also include masking (e.g., dielectric, photoresist material) and/or etching processes intermixed with the additive processes.

FIG. 5 illustrates dielectric material 214 of the first layers 212a formed on the release layer 402 of the carrier 400 and on the conductive material 216, finalizing the first layers 212a. As shown, the dielectric material 214 covers both the exposed top surface of the release layer 402, and the exposed top and side surfaces of the conductive material 216. Further, the dielectric material 214 is omitted from within the exposed gap in the separation section 406, maintaining a portion of the release layer 402 as exposed. The dielectric material 214 can be formed using any suitable additive manufacturing process, such as providing a uniform polyimide layer over the top surface of the release layer 402, and the top and side surfaces of the conductive material 216 in the assembly sections 404 and, optionally, in the separation section 406. The polyimide layer can be selectively cured within the assembly sections 404 using photomasking (e.g., a reticle). Uncured portions of the polyimide within the exposed gap can be removed using any suitable cutting, etching, descum operation, or any similar, suitable method, or a combination thereof, thereby exposing the top surface of the carrier 400 within the exposed gap. The slope on the side surfaces in the dielectric material 214 in the first layer 212a is a result of the process of selectively curing using photomasking and removal of uncured portion.

FIG. 6 illustrates forming a second RDL interposer layer 212b on the first layer 212a, with side legs extending over the first layer 212a and contacting the release layer 402. As shown, the second layer 212b includes conductive material 216 and dielectric material 214, like the first layer 212a. The dielectric material 214 of the second layer 212b, however, extends over the sides of the first layer 212a, and down to the top surface of the release layer 402. The conductive material 216 of the second layer 212b can be formed on the top surface of the first layer 212a following the same, or a similar, process as the conductive material 216 of the first layer 212a. Similarly, the dielectric material 214 of the second layer 212b can be (i) formed on the top and side surfaces of the first layer 212a, and on the conductive material 216 of the second layer 212, and (ii) selectively cured or removed, exposing the carrier 400 within the exposed gap, following the same, or a similar, process as the dielectric material 214 of the first layer 212a.

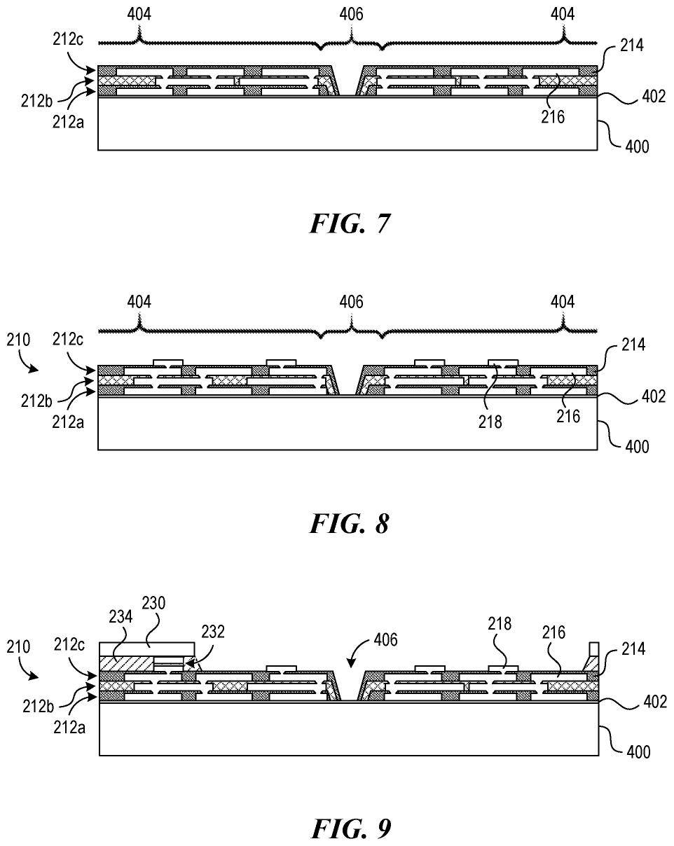

FIG. 7 illustrates forming a third RDL interposer layer 212c on the second layer 212b with side legs extending over the first layer 212a and the second layer 212b, and contacting the release layer 402. As shown, the third layer 212c includes conductive material 216 and dielectric material 214, like the first layer 212a and the second layer 212b. The dielectric material 214 of the third layer 212c, however, extends over the sides of the first layer 212a and over the side legs of the second layer 212b, and down to the top surface of the release layer 402. The conductive material 216 and the dielectric material 214 of the third layer 212b can be formed on the top of the second layer 212b following the same, or a similar, process for the second layer 212b, again exposing the carrier 400 within the exposed gap.

In some embodiments, if the resulting assemblies include RDL interposers with additional layers, one or more additional layers can be forming following the same, or a similar process, as used to form the first, second, and/or third layers 212a, 212b, 212c. Further, in some embodiments, if the resulting assemblies include RDL interposers with sides other than sloped, layered sides, forming the dielectric material 214 can follow a different process. For example, when forming the dielectric material 214 of one or more layers, selectively curing or removing the dielectric material 214 can include using photomasking and/or etching to remove additional, or less, dielectric material 214 from within the exposed gap, thereby modifying the sides of the RDL interposers 210.

FIG. 8 illustrates forming bond pads 218 (e.g., conductive material 216) on the top surface of the third layer 212c, completing the RDL interposers 210. As shown, two bond pads 218 have been formed on each RDL interposer 210 for electrically connecting a controller and/or devices coupled to the RDL interposer 210 with the conductive material 216 therein. The bond pads 218 can be formed using any suitable additive manufacturing process such as, for example, sputtering, physical vapor deposition (PVD), electroplating, lithography, or any other similar process(es), or combination thereof. Further, forming the bond pads 218 can also include masking (e.g., dielectric, photoresist material) and/or etching processes intermixed with the additive processes.

FIG. 9 illustrates controllers 230 physically and electrically coupled to the completed RDL interposers 210. As shown, interconnection structures 232 (e.g., interconnection pillars having solder material thereon) of the controllers 230 are aligned with, and physically and electrically coupled to the bond pads 218 of the RDL interposers 210, placing the controller 230 in electric communication with the RDL interposer 210. Further, an underfill material 234 fills a gap between the bottom surface of the controllers 230 and the top surface of the RDL interposers 210. The interconnection structures 232 can be physically and electrically coupled to the bond pads 218 using a reflow operation. During the reflow operation, the controllers 230 can be placed on the RDL interposers 210 with the interconnection structures 232 aligned with the bond pads 218, and heat and pressure can be applied to melt the solder material therebetween and interconnect the controllers 230 and the RDL interposers 210. The underfill material 234 can be provided via a similar reflow operation, using an injection process, and/or an application process utilizing a capillary effect due to the height of the gap.

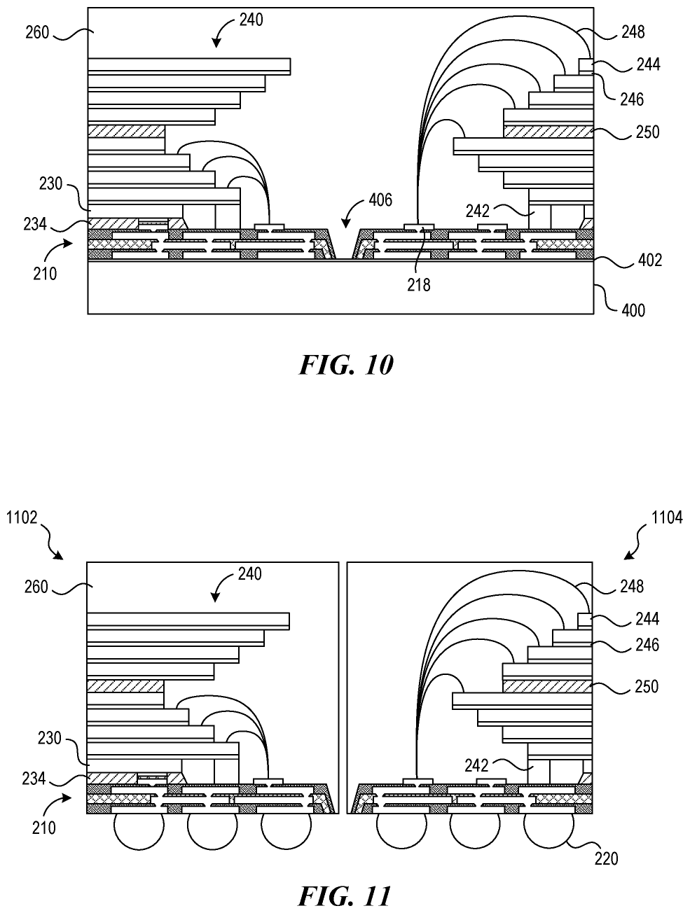

FIG. 10 illustrates an intermediary assembly with device stacks 240 physically and electrically coupled to the RDL interposers 210 and the controllers 230. Further, FIG. 10 illustrates the intermediary assembly with a mold material 260 encasing the RDL interposers 210, the controllers 230, and the device stacks 240, as well as filling the exposed gap between the RDL interposers 210 and contacting the top surface of the release layer 402. That is, within the separation section 406, only mold material 260 is present; the separation section 406 is exclusive of dielectric material 214 and conductive material 216 used in the RDL interposers 210.

The device stacks 240 can be physically coupled to the RDL interposers 210 and the controllers 230 by (i) forming and/or coupling the spacers 242 to the top surfaces of the RDL interposers 210, laterally spaced from the controller, (ii) stacking and coupling a first stack device 244 to the controller 230 and the spacers 242, and (iii) consecutively stacking and coupling stack devices 244 to the first stack device 244 using an adhesive layer 246 and/or a mating compound 250. In some embodiments, stacking and coupling can instead include solder bonding and/or surface bonding consecutive stack devices 244. The stack devices 244 can be electrically coupled to the RDL interposers 210 and the controllers 230 by forming wire traces 248 between a bond pad at the exposed surface of each stack device 244 and one of the bond pads 218 at the top surface of the RDL interposer 210.

The mold material 260 can be applied over the RDL interposers 210, the controllers 230, and the device stacks 240, as well as within the exposed gap between the RDL interposers 210 by applying any suitable mold material over these elements and allowing the mold material 260 to cure. For example, the mold material 260 can be any mold material suitable for encasing the RDL interposers 210, the controllers 230, and the device stacks 240, and flowing within the exposed gap between the RDL interposers 210 to protect these elements against contaminants (e.g., dust, dirt, liquid, smoke, etc.). The mold material 260 be cured using time, heat, and/or curing lights, and etched to form a uniform top surface of the intermediary assembly.

FIG. 11 illustrates the right portion of the first assembly 1102 and the left portion of the second assembly 200, with each of the first and the second assemblies 1104 including edge-protected RDL interposers. As shown, (i) the intermediary assembly is removed from the carrier 400 and the release layer 402, (ii) solder balls 220 are formed at the bond pads 218 on the bottom surface of the RDL interposers 210, and (iii) the resulting assembly is cut along the separation section 406 (see FIG. 10), forming the first assembly 1102 and the second assembly 1104, with a portion of the mold material over and coupled to the side surface of the RDL interposer 210, and between the sides surface of the RDL interposer 210 and the side surface of the assemblies 1102, 1104. Once the intermediary assembly is removed from the carrier 400, the solder balls 220 can be formed using any suitable additive manufacturing process, such as plating. The intermediary assembly can be cut to form the first and the second assemblies 1102, 1104 using any suitable singulation method, such as scribe dicing, blade dicing, laser dicing, and/or plasma dicing.

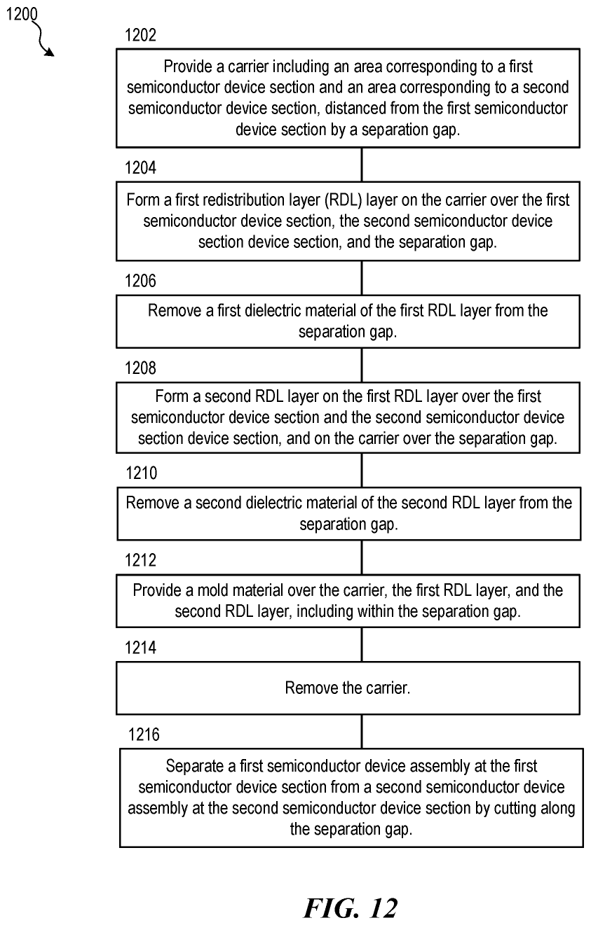

FIG. 12 is a flow diagram illustrating a process 1200 for producing semiconductor devices including edge-protected RDL interposers in accordance with some embodiments of the present technology. The operations of the process 1200 are intended for illustrative purposes and are nonlimiting. In some embodiments, for example, the processes can be accomplished with one or more additional operations not described, without one or more of the operations described, or with operations described and/or not described in an alternative order. The process 1200 can generally include the same operations as illustrated in FIGS. 4-11 of (i) forming an RDL interposer layers on a carrier while maintaining a gap within separation sections (e.g., a separation gap) between semiconductor device assembly sections; (ii) coupling one or more controllers and/or semiconductor devices to the RDL interposer; (iii) providing a mold material over the controllers, the semiconductor devices, and the RLD interposer; (iv) removing the carrier; and (v) separating (e.g., singulating) the semiconductor device assembly within each assembly section from adjacent semiconductor device assemblies by cutting along the separation sections. In some embodiments, all of these operations can be performed by a single entity (e.g., manufacturer, processer) and/or at a single facility. In other embodiments, some of these operations can be performed by a first entity and/or at a first facility and other operations can be performed by one or more other entities and/or at one or more other facilities.

More specifically, as shown in FIG. 12, the process 1200 can include (i) providing a carrier including an area corresponding to a first semiconductor device section and an area corresponding to a second semiconductor device section, distanced from the first semiconductor device section by a separation gap (process portion 1202); forming a first RDL layer on the carrier over the first semiconductor device section, the second semiconductor device section, and the separation gap (process portion 1204); removing a first dielectric material of the first RDL layer from the separation gap (process portion 1206); forming a second RDL layer on the first RDL layer over the first semiconductor device section and the second semiconductor device section device section, and on the carrier over the separation gap (process portion 1208); removing a second dielectric material of the second RDL layer from the separation gap (process portion 1210); providing a mold material over the carrier, the first RDL layer, and the second RDL layer, including within the separation gap (process portion 1212); removing the carrier (process portion 1214); and separating a first semiconductor device assembly at the first semiconductor device section from a second semiconductor device assembly at the second semiconductor device section by cutting along the separation gap (process portion 1216).

Forming the first RDL layer on the provided carrier (process portions 1202, 1204) can include the operations discussed regarding FIGS. 4 and 5 to form conductive material and dielectric material on the carrier. The formed first RDL layer can have a uniform thickness on the carrier (and/or on a release layer of the carrier) over the first and the second semiconductor device sections, and over the separation gap. The first RDL layer over the first and the second semiconductor device sections can include both the conductive material and the dielectric material, and the first RDL layer over the separation gap can exclusively include dielectric material (e.g., the first dielectric material). Portions, or all, of the dielectric material over the first and the second semiconductor device sections can be cured, and the dielectric material over the separation gap can remain uncured.

Removing the first dielectric material (process portion 1206) can include the operations discussed regarding FIG. 5 to remove the dielectric material over the carrier in the separation gap. Removing the dielectric material in the separation gap can expose the top surface of the carrier (and/or the release layer) thereat, and can form side surfaces of the first RDL layer.

Forming the second RDL layer (process portions 1208) can include the operations discussed regarding FIGS. 4 and 5 for forming portions of an RDL layer, and regarding FIG. 6 for identifying the structure of the second RDL layer. The formed second RDL layer can have a uniform thickness on the first RDL layer over the first and the second semiconductor device sections, on the side surfaces of the first RDL layer, and on the carrier (and/or a release layer of the carrier) over the separation gap. The second RDL layer over the first and the second semiconductor device sections can include both the conductive material and the dielectric material, and the second RDL layer over the side surfaces of the first RDL layer and over the separation gap can exclusively include dielectric material (e.g., the second dielectric material). Portions, or all, of the dielectric material over the first and the second semiconductor device sections can be cured, and the dielectric material over the side surfaces and the separation gap can remain uncured.

Removing the second dielectric material (process portion 1210) can include the operations discussed regarding FIG. 5 to remove the dielectric material over the carrier and in the separation gap. Removing the dielectric material in the separation gap can expose the top surface of the carrier (and/or the release layer) thereat, and can form side surfaces of the second RDL layer. In some embodiments, the second dielectric material can be removed to expose the side surfaces of the first RDL layer. Further, the second dielectric material can be removed to expose the side surfaces and a portion of the top surface of the first RDL layer. In some embodiments, process portions 1208 and 1210 can be selectively repeated to form additional RDL layers (e.g., a third, a fourth, a fifth layer, etc.). Once a desired height is achieved, bond pads (and/or other conductive features) can be formed on the top surface of a last RDL layer, as discussed regarding FIG. 8; one or more controllers can be physically and electrically coupled to the last RDL layer, as discussed regarding FIG. 9; and a device stack can be physically coupled to the controller and electrically coupled to the last RDL layer, as discussed regarding FIG. 10.

Providing the mold material (process portion 1212) can include the operations discussed regarding FIG. 10 to apply and cure a mold material over the RDL layers, the controller, and/or the devices. The mold material can be applied to cover the RDL layers, the controller, and the devices, and any gaps therebetween. Further, the mold material can fill the separation gaps between any exposed side surfaces of the RDL layers, contacting the top surface of the carrier (and/or the release layer). Once applied, the mold material can be cured using time, heat, and/or curing lights, or another similar, suitable curing process.

Removing the carrier (process portion 1214) can include the operations discussed regarding FIG. 11 by lifting the RDL layer, the controller, and the devices encased in the mold material from the carrier, or, conversely, lowering the carrier therefrom. Once removed, the first semiconductor device assembly at the first assembly section and the second semiconductor device assembly at the second assembly section can be separated (process portion 1216) following the operations discussed rejection FIG. 11. For example, the mold material can be cut along the separation gaps. That is, the first and the second semiconductor device assemblies, and any additional semiconductor device assemblies, can be singulated along the separation gaps, forming individual semiconductor devices assemblies with RDL interposers having side surface protected by the mold material.

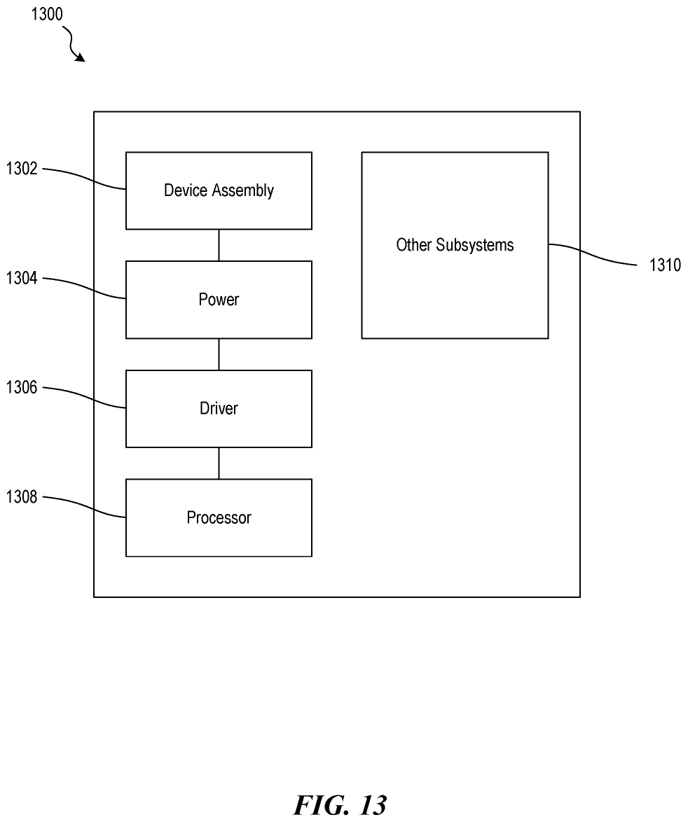

Any one of the semiconductor devices and/or semiconductor device assemblies described above with reference to FIGS. 1-12 can be incorporated into any of a myriad of larger and/or more complex systems, a representative example of which is system 1300 shown schematically in FIG. 13. The system 1300 can include a semiconductor device assembly 1302 (e.g., the assembly 100 of FIG. 1, 400 of FIG. 4, 600 of FIG. 6, 800 of FIG. 8), a power source 1304, a driver 1306, a processor 1308, and/or other subsystems or components 1310. The semiconductor device assembly 1302 can include features generally similar to those of the semiconductor devices and assemblies described above with reference to FIGS. 1-12. The resulting system 1300 can perform any of a wide variety of functions, such as memory storage, data processing, or other suitable functions. Accordingly, representative systems 1300 can include, without limitation, hand-held devices (e.g., mobile phones, tablets, digital readers, and digital audio players), computers, vehicles, appliances, and other products. Components of the system 1300 may be housed in a single unit or distributed over multiple, interconnected units (e.g., through a communications network). The components of the system 1300 can also include remote devices and any of a wide variety of computer-readable media.

For example, the assembly 1302 can be semiconductor device assembly, comprising a redistribution layer (RDL) including a top surface and a side surface intersecting the top surface; and a mold material encasing and directly coupled to at least a portion of the top surface and the side surface of the RDL. The assembly 1302 can further comprise a semiconductor device coupled to the top surface, and the mold material can further encase the semiconductor device. In some embodiments, the semiconductor device is a controller physically and electrically coupled to the RDL, and the assembly further comprises a stack of semiconductor devices coupled to a top surface of the controller, wherein each of the semiconductor devices within the stack of semiconductor devices is in electric communication with the RDL via a wire trace.

In some embodiments, the RDL includes a plurality of RDL layers, wherein each of the RDL layers has a side surface defining a portion of the side surface of the RDL, and wherein each of the side surfaces of the RDL layers are coplanar.

In some embodiments, the side surface of the RDL is perpendicular to the top surface of the RDL.

In some embodiments, the mold material encases and is directly coupled to the entirety of the side surface of the RDL.

In some embodiments, a bottom surface of the RDL defines a bottom surface of the assembly, and wherein the mold material extends to the bottom surface of the assembly at the side surface of the RDL.

As a further example, the assembly 1302 can be a semiconductor device assembly, comprising a redistribution layer (RDL) including a top surface, a bottom surface opposite the top, and a side surface extending between the top surface and the bottom surface, wherein the side surface is sloped relative to the top surface and the bottom surfaces; a semiconductor device coupled to the top surface; and a mold material encasing the semiconductor device and directly coupled to at least a portion of the top surface and the side surface of the RDL.

In some embodiments, the RDL includes a bottom RDL layer, a middle RDL layer, and a top RDL layer, and wherein each of the bottom, the middle, and the top RDL layers has a side surface.

In some embodiments, a width of the bottom RDL layer is greater than a width of the middle RDL layer, and a width of the middle RDL layer is greater than a width of the top RDL layer, and wherein the side surface of each of the RDL layers and a portion of a top surface of the bottom and the middle RDL layers define the side surface of the RDL.

In some embodiments, a portion of the middle RDL layer extends laterally over the side surface of the bottom RDL layer and to a bottom surface of the RDL, and a portion of the top RDL layer extends laterally over the middle RDL layer and to the bottom surface of the RDL, and wherein the portion of the top RDL layer defines the side surface of the RDL.

In some embodiments, a portion of the middle RDL layer extends laterally over the side surface of the bottom RDL layer and to a bottom surface of the RDL, and a width of the top RDL layer is less than a width of the bottom RDL layer, and wherein the portion of the middle RDL layer, a portion of a top surface of the middle RDL layer, and the side surface of the top RDL layer defines the side surface of the RDL.

In some embodiments, a portion of the middle RDL layer extends laterally over the side surface of the bottom RDL layer and to a bottom surface of the RDL, and a width of the top RDL layer is equal to than a width of the middle RDL layer, and wherein the portion of the top RDL layer defines the side surface of the RDL.

In some embodiments, a width of the bottom RDL layer is equal to a width of the middle RDL layer, and a portion of the top RDL layer extends laterally over the side surfaces of the bottom and the middle RDL layers and to a bottom surface of the RDL, and wherein the portion of the top RDL layer defines the side surface of the RDL.

In some embodiments, the RDL further includes a plurality of additional RDL layers.

In some embodiments, each of the top, middle, and bottom RDL layers includes a conductive material and a dielectric material.

In some embodiments, a bottom surface of the RDL defines a bottom surface of the assembly, and wherein the mold material extends to the bottom surface of the assembly at the side surface of the RDL.

A method of manufacturing the assembly 1302 can comprise (i) providing a carrier including an area corresponding to a first semiconductor device section and an area corresponding to a second semiconductor device section, distanced from the first semiconductor device section by a separation gap; (ii) forming a first redistribution layer (RDL) layer on the carrier over the first semiconductor device section, the second semiconductor device section device section, and the separation gap; (iii) removing a first dielectric material of the first RDL layer from the separation gap; (iv) forming a second RDL layer on the first RDL layer over the first semiconductor device section and the second semiconductor device section device section, and on the carrier over the separation gap; (v) removing a second dielectric material of the second RDL layer from the separation gap; and (vi) providing a mold material over the carrier, the first RDL layer, and the second RDL layer, including within the separation gap.

In some embodiments, the method can further comprise, prior to providing the mold material, coupling a first semiconductor device to a top surface of the second RDL layer within the first semiconductor device section; and coupling a second semiconductor device to the top surface of the second RDL layer within the second semiconductor device section.

In some embodiments, the method can further comprise removing the carrier; and separating a first semiconductor device assembly at the first semiconductor device section from a second semiconductor device assembly at the second semiconductor device section by cutting along the separation gap, wherein the mold material covers a side surface of the first and the second RDL layers of the first semiconductor device assembly, and a side surface of the first and the second RDL layers of the second semiconductor device assembly.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. The terms “comprising,” “including,” “having,” and “with” are used throughout to mean including at least the recited feature(s) such that any greater number of the same features and/or additional types of other features are not precluded. Similarly, use of the word “some” is defined to mean “at least one” of the relevant features and/or elements.

As used herein, including in the claims, “and/or” as used in a list of items (for example, a list of items prefaced by a phrase such as “at least one of” or “one or more of”) indicates an inclusive list such that, for example, a list of at least one of A, B, and/or C means: A or B or C; or AB or AC or BC; or ABC (i.e., A and B and C). As used herein, the terms “vertical,” “lateral,” “upper,” “lower,” “above,” and “below” can refer to relative directions or positions of features in the semiconductor devices in view of the orientation shown in the figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation. It should be noted that the methods described above describe possible implementations, and that the operations and the steps may be rearranged or otherwise modified and that other implementations are possible. Furthermore, embodiments from two or more of the methods may be combined.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A semiconductor device assembly, comprising:
a redistribution layer (RDL) including a top surface and a side surface intersecting the top surface; and
a mold material encasing and directly coupled to at least a portion of the top surface and the side surface of the RDL.

2. The assembly of claim 1 further comprising a semiconductor device coupled to the top surface, and wherein the mold material further encases the semiconductor device.

3. The assembly of claim 2, wherein the semiconductor device is a controller physically and electrically coupled to the RDL, and the assembly further comprises a stack of semiconductor devices coupled to a top surface of the controller, wherein each of the semiconductor devices within the stack of semiconductor devices is in electric communication with the RDL via a wire trace.

4. The assembly of claim 1, wherein the RDL includes a plurality of RDL layers, wherein each of the RDL layers has a side surface defining a portion of the side surface of the RDL, and wherein each of the side surfaces of the RDL layers are coplanar.

5. The assembly of claim 1, wherein the side surface of the RDL is perpendicular to the top surface of the RDL.

6. The assembly of claim 1, wherein the mold material encases and is directly coupled to the entirety of the side surface of the RDL.

7. The assembly of claim 1, wherein a bottom surface of the RDL defines a bottom surface of the assembly, and wherein the mold material extends to the bottom surface of the assembly at the side surface of the RDL.

8. A semiconductor device assembly, comprising:
a redistribution layer (RDL) including a top surface, a bottom surface opposite the top, and a side surface extending between the top surface and the bottom surface, wherein the side surface is sloped relative to the top surface and the bottom surfaces;
a semiconductor device coupled to the top surface; and
a mold material encasing the semiconductor device and directly coupled to at least a portion of the top surface and the side surface of the RDL.

9. The assembly of claim 8, wherein the RDL includes a bottom RDL layer, a middle RDL layer, and a top RDL layer, and wherein each of the bottom, the middle, and the top RDL layers has a side surface.

10. The assembly of claim 9, wherein a width of the bottom RDL layer is greater than a width of the middle RDL layer, and a width of the middle RDL layer is greater than a width of the top RDL layer, and wherein the side surface of each of the RDL layers and a portion of a top surface of the bottom and the middle RDL layers define the side surface of the RDL.

11. The assembly of claim 9, wherein a portion of the middle RDL layer extends laterally over the side surface of the bottom RDL layer and to a bottom surface of the RDL, and a portion of the top RDL layer extends laterally over the middle RDL layer and to the bottom surface of the RDL, and wherein the portion of the top RDL layer defines the side surface of the RDL.

12. The assembly of claim 9, wherein a portion of the middle RDL layer extends laterally over the side surface of the bottom RDL layer and to a bottom surface of the RDL, and a width of the top RDL layer is less than a width of the bottom RDL layer, and wherein the portion of the middle RDL layer, a portion of a top surface of the middle RDL layer, and the side surface of the top RDL layer defines the side surface of the RDL.

13. The assembly of claim 9, wherein a portion of the middle RDL layer extends laterally over the side surface of the bottom RDL layer and to a bottom surface of the RDL, and a width of the top RDL layer is equal to than a width of the middle RDL layer, and wherein the portion of the top RDL layer defines the side surface of the RDL.

14. The assembly of claim 9, wherein a width of the bottom RDL layer is equal to a width of the middle RDL layer, and a portion of the top RDL layer extends laterally over the side surfaces of the bottom and the middle RDL layers and to a bottom surface of the RDL, and wherein the portion of the top RDL layer defines the side surface of the RDL.

15. The assembly of claim 9, wherein the RDL further includes a plurality of additional RDL layers.

16. The assembly of claim 9, wherein each of the top, middle, and bottom RDL layers includes a conductive material and a dielectric material.

17. The assembly of claim 8, wherein a bottom surface of the RDL defines a bottom surface of the assembly, and wherein the mold material extends to the bottom surface of the assembly at the side surface of the RDL.

18. A method of manufacturing a semiconductor device assembly, comprising:
providing a carrier including an area corresponding to a first semiconductor device section and an area corresponding to a second semiconductor device section, distanced from the first semiconductor device section by a separation gap;
forming a first redistribution layer (RDL) layer on the carrier over the first semiconductor device section, the second semiconductor device section device section, and the separation gap;
removing a first dielectric material of the first RDL layer from the separation gap;
forming a second RDL layer on the first RDL layer over the first semiconductor device section and the second semiconductor device section device section, and on the carrier over the separation gap;
removing a second dielectric material of the second RDL layer from the separation gap; and
providing a mold material over the carrier, the first RDL layer, and the second RDL layer, including within the separation gap.

19. The method of claim 18 further comprising, prior to providing the mold material:
coupling a first semiconductor device to a top surface of the second RDL layer within the first semiconductor device section; and
coupling a second semiconductor device to the top surface of the second RDL layer within the second semiconductor device section.

20. The method of claim 18 further comprising:
removing the carrier; and
separating a first semiconductor device assembly at the first semiconductor device section from a second semiconductor device assembly at the second semiconductor device section by cutting along the separation gap,
wherein the mold material covers a side surface of the first and the second RDL layers of the first semiconductor device assembly, and a side surface of the first and the second RDL layers of the second semiconductor device assembly.
